(19) United States
(12) Patent Application Publication
(10) Pub. No.: US 2024/0213735 A1
(43) Pub. Date: Jun. 27, 2024

(54) Tunable Integrated Reference Cavity for Laser Stabilization and Spectroscopy

(71) Applicant: The Regents of the University of California, Oakland, CA (US)

(72) Inventors: Andrei Isichenko, Goleta, CA (US); Nitesh Chauhan, Goleta, CA (US); Jiawei Wang, Goleta, CA (US); Mark Harrington, Santa Barbara, CA (US); Kaikai Liu, Santa Barbara, CA (US); Daniel J. Blumenthal, Santa Barbara, CA (US)

(73) Assignee: The Regents of the University of California, Oakland, CA (US)

(21) Appl. No.: 18/394,626

(22) Filed: Dec. 22, 2023

Related U.S. Application Data
(60) Provisional application No. 63/476,778, filed on Dec. 22, 2022.

(51) Int. Cl. H01S 3/137; H01S 3/13

(52) U.S. Cl. CPC H01S 3/137; H01S 3/1305

(57) ABSTRACT

A device may at least one laser with a first optical frequency the at least one laser stabilized to a at least one frequency reference, wherein the at least one laser is locked to the at least one frequency reference. A device may at least one photodiode and at least one laser current servo for locking the at least one laser to the at least one frequency reference. A device may at least one modulator configured to modulate a resonator, wherein the at least one frequency reference is a resonator, the resonator comprising a waveguide core and a tuner, wherein the tuner is laterally offset from the waveguide core.

### CROSS REFERENCE TO RELATED APPLICATIONS

The current application claims the benefit of and priority under 35 U.S.C. § 119(e) to U.S. Provisional Patent Application No. 63/476,778 entitled “Tunable Integrated Reference Cavity for Laser Stabilization and Spectroscopy” filed Dec. 22, 2022, the disclosure of which is incorporated herein by reference in its entirety for all purposes.

### FIELD OF THE INVENTION

The present invention generally relates to photonic integrated circuits incorporating frequency modulated lasers. In particular it relates to photonic integrated circuits incorporating frequency modulated Brillouin lasers.

### BACKGROUND

In traditional systems, frequency stabilization, including linewidth narrowing and/or carrier stabilization, can be achieved with table-top reference cavities, compact bulk-optic whispering-gallery-mode resonators (WGMs), fused silica rods and/or photonic-integrated resonators. In some cases, these platforms can be susceptible to absolute frequency drift. Absolute frequency drift can be reduced by locking the laser to an atomic reference such as a rubidium saturation absorption spectroscopy cell. The dual-lock to both a reference cavity and an atomic reference can often be achieved with a power-consuming, difficult to integrate, acousto-optic frequency shifter. Scanning and alignment of locked lasers to a desired atomic transition can be performed by a bulk microcavity Brillouin laser with optical power induced frequency tuning and/or with a piezoelectric actuator on a WGM crystal in an injection locked laser for probing a rubidium cell.

### SUMMARY OF THE INVENTION

In an embodiment, a laser system is on a photonic integrated circuit, the photonic integrated circuit including: at least one laser with an optical frequency the at least one laser stabilized to an at least one frequency reference, wherein the at least one laser is locked to the at least one frequency reference; at least one photodiode and at least one laser current servo for locking the at least one laser to the at least one frequency reference; and at least one modulator configured to modulate a resonator, wherein the modulator received an input from an optical frequency discriminator system and the optical frequency system receives an optical input from a laser output; wherein the at least one frequency reference is a resonator, the resonator including a waveguide core and a tuner, wherein the tuner is laterally offset from the waveguide core.

In another embodiment, the tuner includes a tuner configured by a tuning effect, the tuning effect selected from a list consisting of electro-optic tuning effect, stress-optic tuning effect, current-injection tuning effect, and thermo-optic tuning effect.

In yet another embodiment, the laser optical frequency is selected from a list consisting of Deep UV, UV, near UV, Visible, Near IR, Mid IR and IR wavelengths.

In still another embodiment, the at least one laser, the at least one photodiode, the at least one frequency reference, and the at least one modulator are integrated to an integrated circuit using a material selected from a group consisting of silicon nitride, tantalum pentoxide, alumina nitride, and alumina oxide.

In another embodiment again, the photonic integrated circuit is CMOS foundry compatible waveguide circuit.

In another additional embodiment, the resonator waveguide core and resonator tuner are separated by a cladding layer, the cladding layer sufficiently thick to prevent optical interaction between the resonator tuner and the waveguide core.

In yet another embodiment again, the resonator is configured to narrow a linewidth of the laser and reduce the laser frequency and phase noise.

In still another embodiment again, the resonator tuner is configured to tune the laser without affecting noise properties of the laser.

In yet still another embodiment again, the laser is from a list of lasers including Fabry-Perot, DFB, DBR, EDBR, self-injection locked and stimulated Brillouin laser.

In an embodiment, a laser system is on a photonic integrated circuit, the photonic integrated circuit including: a laser with an optical frequency, the laser stabilized to a frequency reference, wherein the laser is locked to the frequency reference; at least one photodiode and a first voltage modulator for locking the laser to the frequency reference; a second voltage modulator configured to modulate the frequency reference, wherein the laser stabilized to the modulated frequency reference is input to a physics package; and a PDH lock loop configured to lock the stabilized laser and frequency reference to an optical transition of atoms in the physics package; wherein the frequency reference is a resonator, the resonator including a waveguide core and a tuner, wherein the tuner is laterally offset from the waveguide core.

In a further embodiment, the tuner includes a tuner configured by a tuning effect, the tuning effect selected from a list consisting of electro-optic tuning effect, stress-optic tuning effect, current-injection tuning effect, and thermo-optic tuning effect.

In a yet further embodiment, the laser optical frequency is selected from a list consisting of Deep UV, UV, near UV, Visible, Near IR, Mid IR and IR wavelengths.

In a still further embodiment, the laser, the at least one photodiode, the frequency reference, and a first voltage modulator are integrated to an integrated circuit using a material selected from a group consisting of silicon nitride, tantalum pentoxide, alumina nitride, and alumina oxide.

In another further embodiment, the photonic integrated circuit is CMOS foundry compatible waveguide circuit.

In a still yet further embodiment, the resonator waveguide core and resonator tuner are separated by a cladding layer, the cladding layer sufficiently thick to prevent optical interaction between the resonator tuner and the waveguide core.

In a still further embodiment again, the resonator tuner is configured to narrow a linewidth of the laser.

In a yet further embodiment again, the resonator tuner is configured to tuning the laser without affecting noise properties of the laser.

In a still yet further embodiment again, a laser output comes from a circulator, the circulator positioned along a waveguide, and located between the laser and the resonator.

In a further additional embodiment, the physics package is a rubidium two-photon physics package.

In a further additional embodiment again, a laser output is provided to an optical frequency discriminator.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1A conceptually illustrates an example SiN device with metal traces and metal probes used to actuate the thermo-optic tuner.

FIG. 1B conceptually illustrates a plot of example Q measurements of a resonator at 780 nm yielding Qᵢ=118×10⁶ and 0.44 dB/m loss.

FIG. 1C conceptually illustrates an example plot showing static tuning of the thermo-optic actuator with high extinction ratio and >50 M loaded Q across the tuning range is depicted in FIG. 1C.

FIG. 1D conceptually illustrates an example plot of a linear fit used to extract thermo-optic tuning coefficient yields of 20 MHz/mW.

FIG. 2 conceptually illustrates a schematic of example Pound-Drever-Hall (PDH) laser stabilization to the resonator reference cavity with thermo-optic tuner.

FIG. 3A conceptually illustrates a plot of example frequency noise data of a PDH-locked laser for different tuner powers.

FIG. 3B conceptually illustrates an example plot of reference laser beat note frequency time trace during thermal tuner step inputs with rise and fall times from an exponential fit.

FIG. 3C. conceptually illustrates an example plot of the voltage ramp to the thermal tuner for scanning a locked laser across rubidium transitions.

FIGS. 4A through 4B conceptually illustrates a laser system for frequency modulation for direct frequency modulated ultra-narrow linewidth SBL.

FIGS. 5A through 5B conceptually illustrates example frequency response data from an example direct frequency modulated ultra-narrow linewidth SBL.

FIG. 6A conceptually illustrates an example measurement laser system for measuring the presence and relative power of the SBS using an optical spectrum analyzer.

FIG. 6B conceptually illustrates example OFD frequency noise from said laser system.

FIG. 7 conceptually illustrates an example system diagram of a dual-stage lock and probe laser stabilization to a two-photon physics package.

FIG. 8A through 8C conceptually illustrate example data obtained by testing a dual-stage lock and probe laser stabilization to a two-photon physics package.

### DETAILED DESCRIPTION

Taking technology that has typically occupied lab benches and racks, and moving it to the chip-scale through integration can realize various benefits. Benefits of integration can include reduced size and weight, reduced cost, lower power consumption, improved controllability and reliability, and/or improved repeatability and manufacturability. These advantages can be key to commercial applications spanning a wide range of uses such as atomic, quantum, communications, metrology, mobile and/or space-based applications. Various embodiments, as described herein, can include chip-scale stabilization of lasers. Chip-scale stabilized lasers can enable larger numbers of stabilized lasers to be used in applications that require large numbers of lasers. Such application can include, for example quantum computing. Other applications of chip-scale stabilized lasers can include the realization of small, light-weight systems including space-based systems.

In accordance with many embodiments of the invention, integrated narrow-linewidth lasers can be critical for the miniaturization of atomic systems for quantum sensing, computing, precision navigation, timekeeping, and/or high capacity optical communications. Atomic and other systems can require laser stabilization for both linewidth narrowing (e.g., phase noise reduction) and/or frequency stabilization with respect to an atomic transition and/or other frequency standard.

In accordance with several embodiments of the invention, a tunable, ultra-high quality factor (Q) reference cavity (e.g., an integrated optical reference cavity) can serve for laser stabilization (e.g., linewidth narrowing) and/or tuning and/or sweeping of the stabilized laser. In several embodiments laser stabilization and tuning or sweeping of the stabilized laser is performed simultaneously by a reference cavity. Such a reference cavity can address laser frequency stabilization and spectroscopy (e.g., scanning, probing and/or locking to rubidium and/or other atomic species).

Desirable properties of an integrated optical reference cavity can include low loss, high Q and low noise. In a number of embodiments these desirable properties are achieved while at the same time allowing the center resonance of the cavity to be tuned. Tuning techniques can include electro-optic, current-injection, thermal and/or stress-optic tuning techniques. In some embodiments, thermal and/or stress-optic tuning techniques do not affect the optical properties of the reference cavity. Such tuning can, in a number of embodiments, happen at fast enough rates to enable sweeping, control, locking and/or other spectroscopic functions.

Integrated narrow-linewidth lasers in the near-IR and visible wavelength range are important for next-generation atomic systems for quantum sensing, navigation, and precision timekeeping. These applications can demand exceptional frequency noise characteristics, narrow fundamental linewidths, narrow integral linewidths, and/or agile laser frequency control with respect to atomic transitions that maintains spectrally pure frequency noise characteristics. Laser frequency noise can be reduced by Pound-Drever-Hall (PDH) locking to an ultra-stable table-scale Fabry-Pérot vacuum-spaced silicon mirror reference cavity. Miniaturization of these types of lasers can be achieved with self-injection locking using whispering-gallery-mode resonators (WGMRs), integrated photonics, PDH locking to low-FSR coil resonators, and/or with stimulated Brillouin lasers (SBLs) which can narrow laser noise far-from-carrier. Bulk-optic modulators are typically used to further stabilize a cavity-locked laser with respect to an atomic transition or to apply sidebands. Compact stabilization schemes have used actuators to tune and modulate the cavity for locking and recently this approach has been extended to integrated devices such as in silicon nitride. However, producing ultra-narrow laser linewidth while maintaining frequency modulation capability has been a particular challenge in integrated devices in the visible and near-IR.

In accordance with several embodiments of the invention, a photonic-integrated 780 nm stimulated Brillouin laser (SBL) can maintain around sub-25 Hz fundamental and around sub-1.5 kHz integral linewidths with direct frequency modulation at around 22 kHz using a thermo-optic controlled SBS cavity. In numerous embodiments, a modulated (e.g., thermo-optically modulated, PZT modulated, and/or otherwise modulated) integrated Brillouin laser resonator cavity can be pumped with a 780 nm DBR semiconductor laser. Such a Brillouin laser resonator cavity can result in a minimum frequency noise of around 7.6 Hz\hat{ }2/Hz at around 1 MHz offset from carrier corresponding to a fundamental linewidth of around 24 Hz. The integral linewidth is reduced from around 180 kHz to around 1.4 kHz and the heater modulation of over around 20 kHz in accordance with many embodiments. Multi-stage laser stabilization and/or real-time hyper-fine transition atomic spectroscopy can be beneficial for atomic and quantum experiments, and in particular for rubidium applications such as two-photon optical atomic clocks and/or in Raman probe lasers for atom interferometers operation at 778 nm and/or 780 nm.

In various embodiments, a SiN device with metal traces connected to metal probes can be used to actuate a thermo-optic tuner. Wire bonding or other electrical connection to the thermal electrode can be used in several embodiments. An example

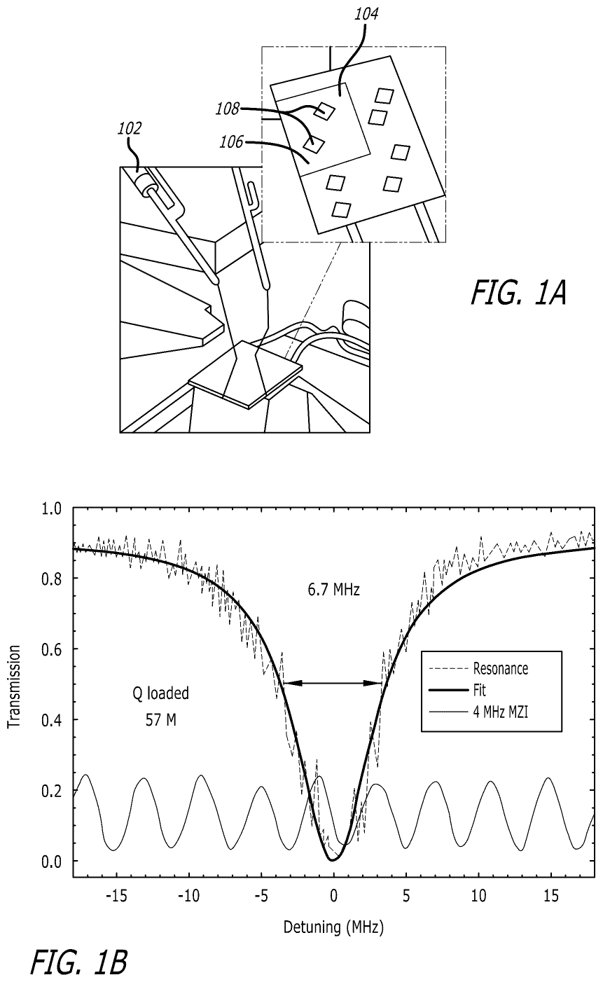

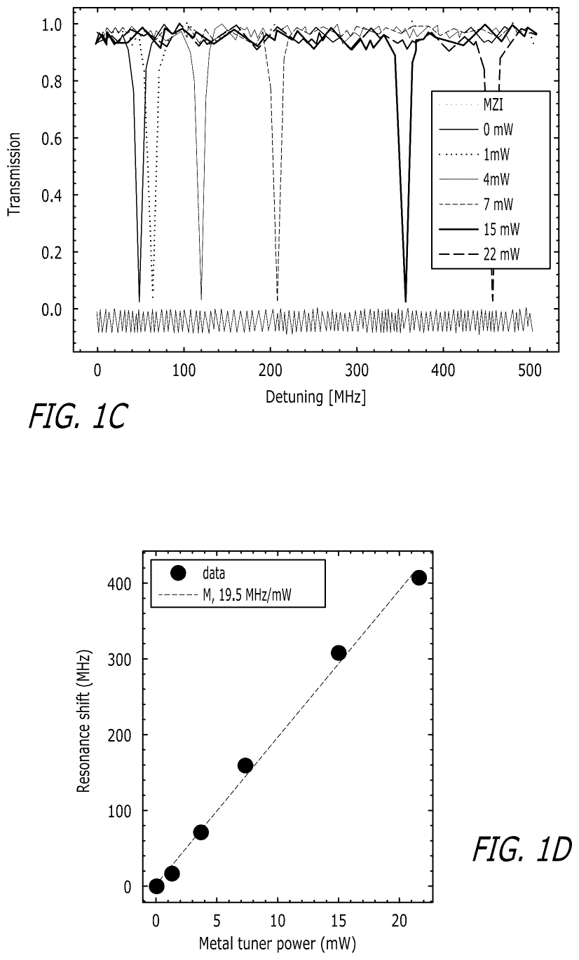

SiN device with metal traces and metal probes used to actuate the thermo-optic tuner is conceptually illustrated in FIG. 1A. The probes 102 can be used to actuate the thermo-optic tuner 104. The thermo-optic tuner 104 can include metal pads 108 and a metal semi-circle 106. The thermo-optic tuner can be arranged along a resonator waveguide. In several embodiments, electrodes can be platinum electrodes. A plot of example Q measurements of a resonator at 780 nm yielding Qᵢ=118×10⁶ and 0.44 dB/m loss is depicted in FIG. 1B. A plot showing example static tuning of the thermo-optic actuator with high extinction ratio and >50 M loaded Q across the tuning range is depicted in FIG. 1C. A plot of an example linear fit used to extract thermo-optic tuning coefficient yields of 20 MHz/mW is depicted in FIG. 1D. It is understood that thermo-optic tuning coefficients can vary according to various embodiments.

In several embodiments, a resonator waveguide (e.g., reference cavity) design can include an around 15 μm SiO2 lower cladding, an around 40 nm thick Si3N4 core, an around 4 μm wide Si3N4 core, and/or an around 6 μm SiO2 upper cladding. The resonator can support fundamental transverse electric (TE) and transverse magnetic (TM) modes. In various embodiments, a fundamental TM mode can be selected for the resonator due to its low waveguide loss. Resonators have a 5.8 mm radius and are nearly critically coupled in several embodiments. Resonators can be coupled to platinum electrodes that are around 250 nm thick and/or around 100 μm wide. The platinum electrodes can be deposited over the oxide upper cladding with an offset (e.g., an offset of around 5 μm) from the resonator waveguide in various embodiments. The offset can function to maintain a high optical Q.

In accordance with many embodiments of the invention, optical Q can be measured using an unbalanced Mach-Zehnder interferometer (MZI). The MZI can be used with a 4 MHz free spectral range (FSR) to calibrate the laser frequency detuning. In some embodiments, a Qi=118 M and a propagation loss of 0.44 dB/m can be extracted from a loaded Q=57 M as shown in FIG. 1B. A relative resonance shift associated with several embodiments, as a function of different tuning powers is shown in FIG. 1C. A linear tuning coefficient of 20 MHz/mW can be associated with various embodiments, and is shown in FIG. 1D. A tuning range of 400 MHz can be sufficient to cover the rubidium atom spectroscopy peaks of interest for rubidium saturation absorption spectroscopy in accordance with numerous embodiments of the invention.

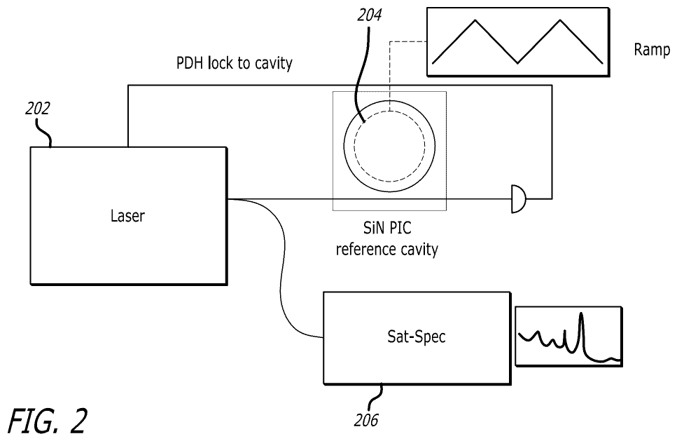

Various embodiments can perform Pound-Drever-Hall laser stabilization to a resonator reference cavity with a thermo-optic tuner. A schematic of example Pound-Drever-Hall (PDH) laser stabilization to the resonator reference cavity with thermo-optic tuner is depicted in FIG. 2. A laser (e.g., a 780 nm semiconductor laser) 202 can have a PDH lock to a reference cavity 204. The laser 202 can also be coupled to a saturation spectroscopy cell (e.g., a Rubidium saturation spectroscopy cell) 206.

While specific methods and/or systems for Pound-Drever-Hall (PDH) laser stabilization to the resonator reference cavity with thermo-optic tuner are described above, any of a variety of methods and/or systems can be utilized as a Pound-Drever-Hall (PDH) laser stabilization to the resonator reference cavity with thermo-optic tuner as appropriate to the requirements of specific applications. In certain embodiments, steps and/or components may be performed and/or configured in any order, sequence, and/or configuration not limited to the order, sequence and/or configuration shown and described. In a number of embodiments, some of the above steps may be executed or performed substantially simultaneously where appropriate or in parallel to reduce latency and processing times. In some embodiments, one or more of the above steps and/or components can be rearranged or omitted. Although the above embodiments of the invention are described in reference to laser system for Pound-Drever-Hall (PDH) laser stabilization to the resonator reference cavity with thermo-optic tuner, the techniques disclosed herein may be used in any type of integrated optical system. The techniques disclosed herein may be used within any of the integrated optical systems, laser systems, and/or other components and/or systems as described herein.

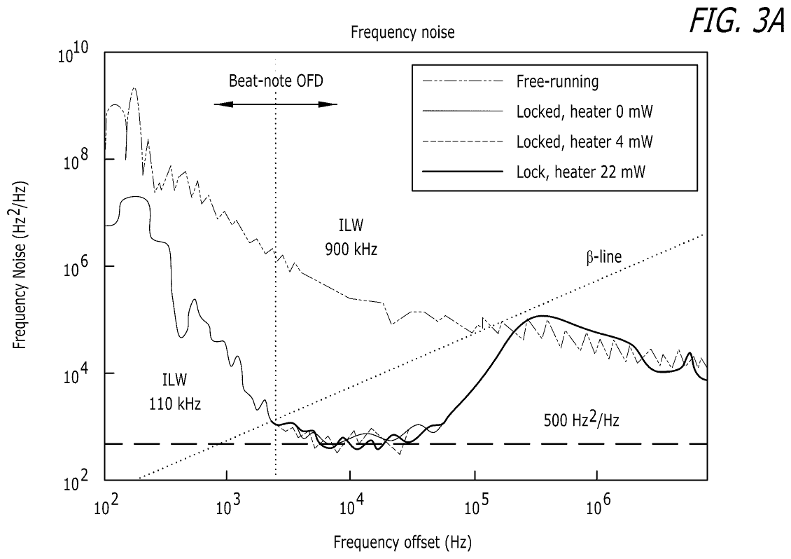

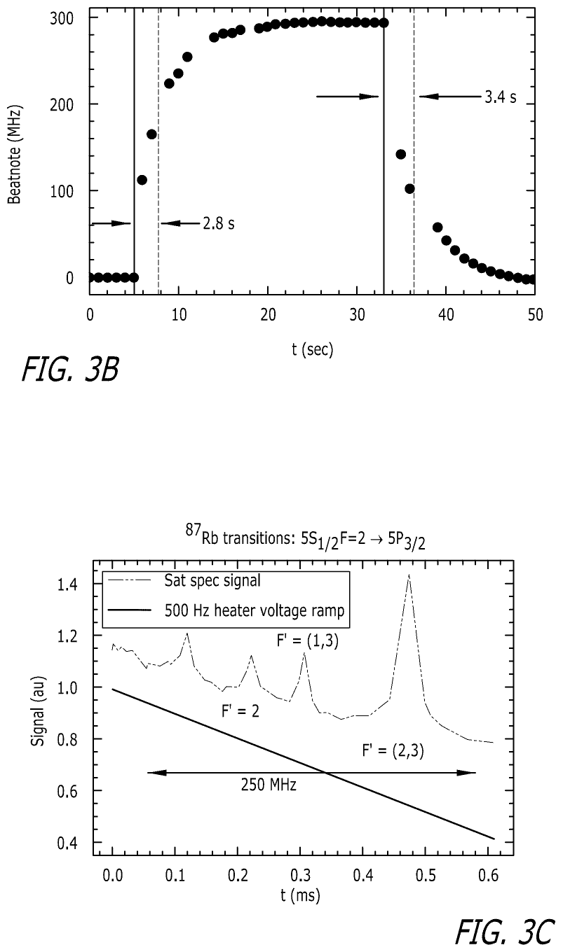

A plot of frequency noise data of a PDH-locked laser for different tuner powers is depicted in FIG. 3A. A plot of reference laser beat note frequency time trace during thermal tuner step inputs with rise and fall times from an exponential fit is depicted in FIG. 3B. A plot of the voltage ramp to the thermal tuner for scanning a locked laser across rubidium transitions is depicted in FIG. 3C.

In various embodiments, a high optical Q and a nearly critically coupled resonance can enable Pound-Drever-Hall (PDH) locking of a commercial 780 nm DBR (distributed Bragg reflector) semiconductor laser for laser noise reduction. Locked laser frequency noise (FN) can be measured using an optical frequency discriminator (OFD) and a beat-note measurement with a low-drift reference laser.

An example FN, of the free running and locked laser is shown in FIG. 3A. A β-separation integral linewidth (ILW, in the range plotted) for the free-running and stabilized laser can be 900 kHz and 110 kHz, respectively. In various embodiments, a locked laser FN can reach 500 Hz2/Hz at 10 kHz frequency offset and can be unchanged for different heater powers. A beat-note of a laser with a reference laser during a step input to the thermal tuner can be measured. In accordance with several embodiments of the invention, a locked laser can track the resonator and the exponential fit time constant for the rise (fall) time of around 2.8 (3.4)s.

Numerous embodiments, can ramp the voltage applied to the tuner to scan a locked laser across an ⁸⁷ Rb D2 line hyperfine transition. A saturation absorption spectroscopy signal is shown in FIG. 2(D). In various embodiments, a 500 Hz ramp rate can be applied to the tuner, which can be a sufficient speed for locking to a hyperfine transition to reduce long-term laser frequency drift.

In accordance with numerous embodiments of the invention, a tunable, ultra-high 118 million Q reference resonator at the rubidium atom 780 nm wavelength achieves a low waveguide loss. The tuning range and scan rate can be applicable to a two-stage stabilization scheme to reduce laser linewidth with the tunable resonator and/or reduce drift by engaging the lock to a rubidium spectroscopy cell. In several embodiments, lasers can be used for cooling of rubidium atoms, for improved sensitivity in a cold atom sensor, and/or in a two-photon optical clock. Narrow-linewidth tunable lasers, as included in various embodiments can be integrated into compact atomic systems.

In some embodiments, a 780 nm semiconductor laser (e.g., a 780 nm semiconductor laser) can be stabilized to a thermally tuned photonic resonator (e.g., a 118 million Q silicon nitride bus-coupled ring photonic resonator). By providing a tuning mechanism (e.g., thermal tuners and/or a stress-optic tuners) to a cavity, stabilized lasers can be swept by 400 MHz and can probe rubidium transitions at a 500 Hz rate in accordance with embodiments of the invention.

Thermo-optically tunable, ultra-high-quality factor (Q) reference cavities, in various embodiments, provide 780 nm laser frequency stabilization and control for probing the D2 line (e.g., D2 fluorescence spectrum) of atoms (e.g., rubidium, strontium, cesium and/or other suitable atoms). Resonators (e.g., Thermo-optically tunable, ultra-high-quality factor (Q) reference cavities, tunable resonator) can be fabricated in a silicon nitride (Si3N4) photonic-integration platform is accordance with numerous embodiments of the invention. In some embodiments, resonators can be tuned across the rubidium resonances using a resistive metal layer thermal tuner deposited on the upper cladding near the waveguide. In several embodiments, tunable resonators can have around a 118 million quality factor (Q) with around a 0.44 dB/m loss and a thermo-optic tuning range of around 400 MHz or more. In various embodiments, stress-optic tuning, such as PZT and/or aluminum nitride (AlN) can be used in place of or in addition to thermal tuners. In several embodiments, well-known tuning mechanisms including mechanical and electrooptic can be used.

In a number of embodiments, resonators can be used as tunable reference cavities for 780 nm laser linewidth reduction. Linewidth narrowed lasers can, in various embodiments, be scanned across the rubidium transitions by scanning a resonator thermal tuner at a rate up to around 500 Hz. In some embodiments scanning can be performed across various atomic wavelength transitions (e.g., 674 nm for strontium ions and 698 nm for neutral strontium atoms). Wavelengths and atom transitions can be selected based on a particular application.

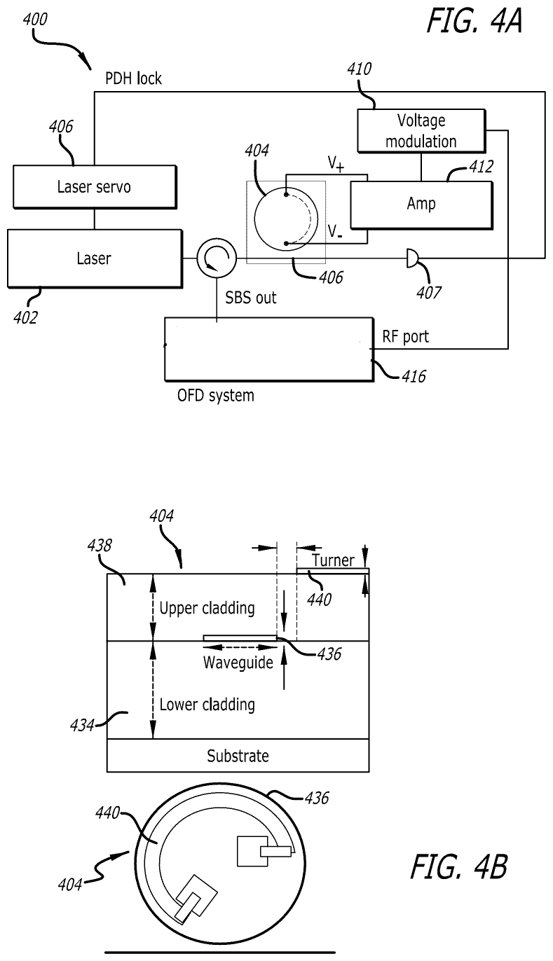

An example laser system for frequency modulation for direct frequency modulated ultra-narrow linewidth SBL is shown in FIGS. 4A through 4B

Turning to FIG. 4A, a laser system 400 can include a laser 402 (e.g., a 780 nm DBR laser). The laser 402 can be used to pump a resonator 404 (e.g., a thermally modulated SBL laser cavity). A resonator can have a directly modulated cavity resonance. Such a configuration can be used for narrow SBL and/or to directly modulate a cavity resonance while maintaining superb frequency noise properties. In several embodiments, a resonator can have a radius of around 5.84 mm. Resonators can have an around 5.456 GHz FSR and/or can have an FSR which is phase matched to four times the Brillouin gain shift of 21.8 GHz at 780 nm (e.g., for a corresponding 780 nm laser). The laser system 400 can be implemented on a photonic integrated circuit.

A top view and cross-section of an example resonator are conceptually illustrated in FIG. 4B. The photonic integrated resonator 404 can have a lower cladding 434. In some embodiments, a lower cladding can be 15 μm thick, and/or made of SiO₂. On top of the lower cladding can be a waveguide core 436. The waveguide core can, in several embodiments, be 40 nm thick, 4 μm wide, and/or made from Si₃N₄. The waveguide core can be circular with a radius of around 5.84 mm. The waveguide core 436 can be between the lower cladding 434 and an upper cladding 438. In many embodiments, upper cladding can be 6 μm thick and/or can be made of SiO₂. Mounted on top of the upper cladding 438 and/or offset from the waveguide core 436 can be a tuner 440. In many embodiments, the tuner can be an electrode (e.g., a platinum electrode). Electrodes can be 250 nm thick and/or 100 μm wide in accordance with embodiments of the invention. The tuner 440 can be laterally offset from the waveguide core 436. The offset between the tuner and the waveguide core can be about 5 μm in several embodiments. Tuners can rely on various effects to tune a resonator. Example effects include at least thermal effects and/or piezoelectric effects. In several embodiments, the offset can be a distance that is greater than the width of the waveguide core. In many embodiments, the resonator waveguide core and resonator tuner are separated by a cladding layer, and the cladding layer can be sufficiently thick to prevent optical interaction between the resonator tuner and the waveguide core.

The resonator 404 can be located proximate to a waveguide 406. The position such that the ring-bus coupling gap (e.g., the resonator 404-waveguide 406 coupling gap) is designed to couple the fundamental TM mode. In several embodiments, a Qi is around 118 M, QL is around 57 M, and/or a propagation loss is around 0.44 dB/m. In accordance with many embodiments of the invention, a metal electrode is used to tune the resonance. Linear tuning can be around 19.5 MHz/mW.

In various embodiments, lasers can be Fabry-Perot, DFB, DBR, EDBR, self-injection locked and/or stimulated Brillouin lasers. Each of the specific examples herein can use any of these lasers.

In an example device, the SBS threshold for S1 is 0.9 mW and the S1 (e.g., first order Stokes in the stimulated Brillouin scattering process) is ˜15 dB above the pump when operating near S2 (e.g., second order Stokes in the stimulated Brillouin scattering process) threshold. The resonator 404 can be pumped with the laser 402 (e.g., a commercial 780 nm DBR laser). In some embodiments, lasers can be lasers with a frequency in the visible spectrum. Laser can have laser optical frequency selected from Deep UV, UV, near UV, Visible, Near IR, Mid IR and IR wavelengths. The laser 402 can be PDH locked to the resonator using a laser current servo 408. In various embodiments, the laser can have an on-chip power (e.g., an on-chip power of around 4 mW) that is near the S2 threshold which can result in a minimum fundamental linewidth. When locked, a waveform generator 410 and a voltage amplifier 412 (e.g., a 10× voltage amplifier) can be used to modulate the metal electrode resulting in a modulation of the locked SBS laser frequency. The SBS laser output (e.g., with a power of around 0.2 mW) can be measured with an OFD system. In several embodiments, an OFD system can include an unbalanced MZI (UMZI) optical frequency discriminator (OFD) with an RF output port of a balanced photodetector measuring the fast modulation of the laser frequency.

While specific methods and/or systems for laser system for frequency modulation for direct frequency modulated ultra-narrow linewidth SBL are described above, any of a variety of methods and/or systems can be utilized as a laser system for frequency modulation for direct frequency modulated ultra-narrow linewidth SBL as appropriate to the requirements of specific applications. In certain embodiments, steps and/or components may be performed and/or configured in any order, sequence, and/or configuration not limited to the order, sequence and/or configuration shown and described. In a number of embodiments, some of the above steps may be executed or performed substantially simultaneously where appropriate or in parallel to reduce latency and processing times. In some embodiments, one or more of the above steps and/or components can be rearranged or omitted. Although the above embodiments of the invention are described in reference to laser system for frequency modulation for direct frequency modulated ultra-narrow linewidth SBL, the techniques disclosed herein may be used in any type of integrated optical system. The techniques disclosed herein may be used within any of the integrated optical systems, laser systems, and/or other components and/or systems as described herein.

Photonic integrated circuits, in accordance with embodiments of the invention, can include materials selected from a group consisting of silicon nitride, tantalum pentoxide, alumina nitride, and alumina oxide. These materials can be used to integrate various components to a photonic integrated circuit. A photonic integrated circuit can be a CMOS foundry compatible waveguide circuit (e.g., a Si3N4 waveguide circuit).

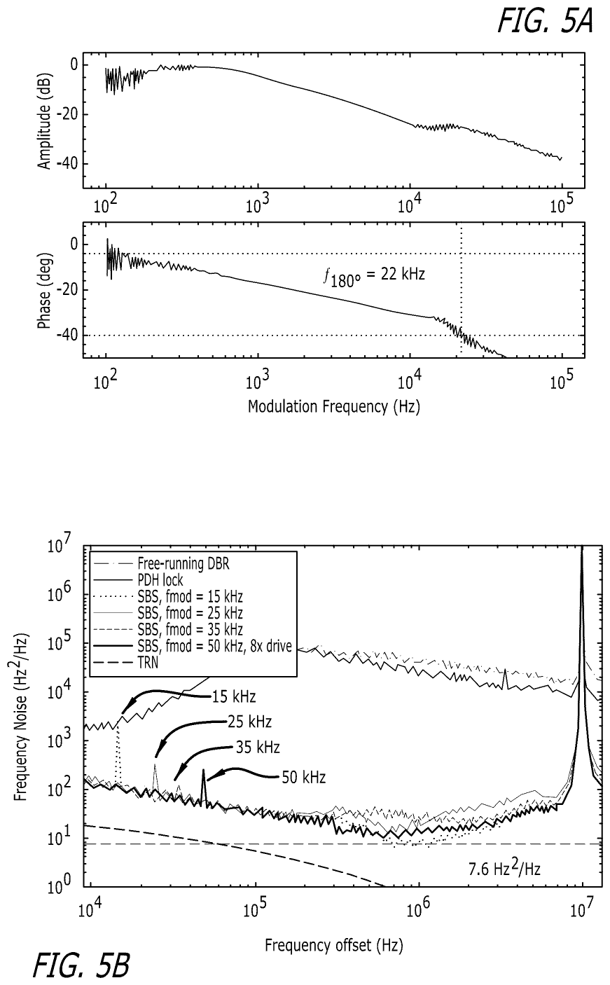

Example frequency response data from an example direct frequency modulated ultra-narrow linewidth SBL are shown in FIG. 5A through 5B. The example data in FIG. 5A corresponds to SBS laser frequency response measurements by modulating the thermal tuner and measuring the RF port of the balanced photodetector signal from the UMZI. The example data in FIG. 5B corresponds to Frequency noise acquired with OFD system for free-running laser, PDH lock only (below SBS threshold), and while pumping SBS with different heater modulation frequencies. For f_{mod}=50 kHz the drive amplitude is around 8 times larger for the example data.

The example data show a f_{180°} point of around 22 kHz. The same OFD measurement can be used to measure the laser frequency noise system to extract the SBS laser linewidth. As shown by the data, the high Q and the good overlap of the Brillouin gain profile and resonator FSRs results in a strong reduction in the laser frequency noise at frequency offsets above 1 kHz (FIG. 5B). In at least one depicted data set, the SBS measurement shows that the free-running laser 1/π integral linewidth is reduced from 180 kHz to 1.4 kHz. The fundamental linewidth is reduced from 33 kHz to 24 Hz, a reduction of over 30 dB. During these measurements, the metal electrodes are modulated at 15, 25, and 35 kHz at 250 mVpp and at 50 kHz at 2 Vpp. The spurs of the OFD frequency noise indicate that the bandwidth of the modulation can reach over 30 kHz. The discrepancy in the minimum fundamental linewidth during these traces is related to fluctuations in the on-chip power and pump light leakage into the frequency noise measurement system.

In accordance with embodiments of the invention, a laser system can include a frequency modulated, narrow-linewidth 780 SBS laser with a 24 Hz fundamental and 1.4 kHz integral linewidth, capable of frequency modulation of over 20 kHz. The sub-mW SBS threshold can enable operation without an amplifier for the 780 nm DBR pump laser. Combined with the large tuning range of the metallized device using a robust PDH lock, the fast modulation speed can be used for stabilization to rubidium spectroscopy. Operation can be extended for 2-photon rubidium spectroscopy at 778 nm, where the short-term clock stability may be limited by laser frequency noise at frequency offsets 50-100 kHz due to the intermodulation noise effect in accordance with many embodiments. Fast, agile laser frequency control can be used for laser stabilization in photonic-integrated cold atom experiments for different cooling sequences and/or beat-note stabilization to enable next-generation compact atomic systems in several embodiments.

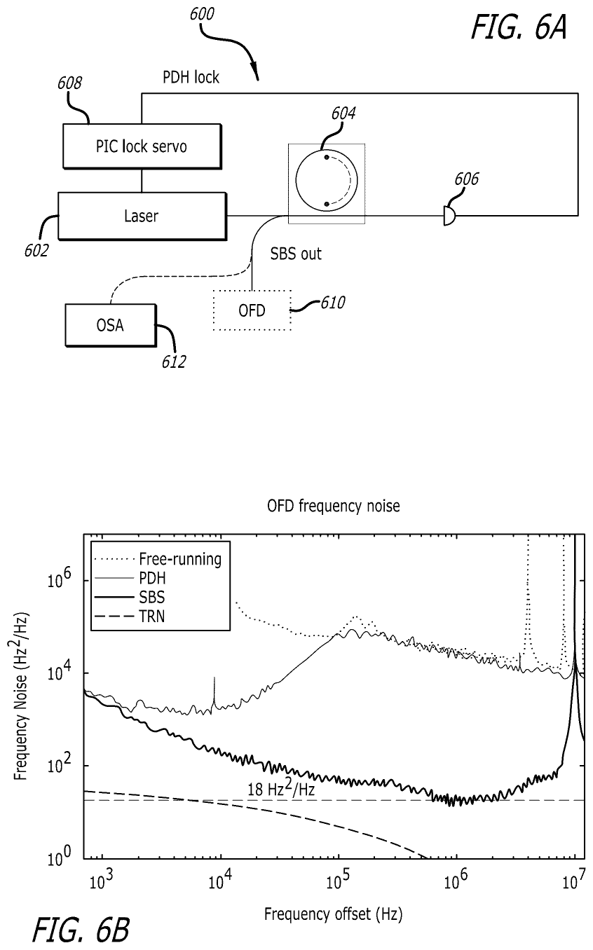

An example measurement laser system for measuring the presence and relative power of the SBS using an optical spectrum analyzer (OSA) is conceptually illustrated in FIG. 6A. FIG. 6B illustrates example OFD frequency noise from said laser system. A laser system 600 can include a laser 602. The laser 602 can pump a resonator 604. The laser can be PDH locked to the resonator 604 using a laser current servo 608 and a photodiode 606. An SBS outlet can link the system to an OSA 612 and/or an optical frequency discriminator (OFD) 610. The laser system 600 can be implemented on a photonic integrated circuit.

While specific methods and/or systems for measurement laser systems for measuring the presence and relative power of the SBS using an optical spectrum analyzer are described above, any of a variety of methods and/or systems can be utilized as a measurement laser system for measuring the presence and relative power of the SBS using an optical spectrum analyzer as appropriate to the requirements of specific applications. In certain embodiments, steps and/or components may be performed and/or configured in any order, sequence, and/or configuration not limited to the order, sequence and/or configuration shown and described. In a number of embodiments, some of the above steps may be executed or performed substantially simultaneously where appropriate or in parallel to reduce latency and processing times. In some embodiments, one or more of the above steps and/or components can be rearranged or omitted. Although the above embodiments of the invention are described in reference to a measurement laser system for measuring the presence and relative power of the SBS using an optical spectrum analyzer, the techniques disclosed herein may be used in any type of integrated optical system. The techniques disclosed herein may be used within any of the integrated optical systems, laser systems, and/or other components and/or systems as described herein.

In accordance with many embodiments, a thermo-optically tunable (e.g., thermo-optically, electro-optically, stress-optically) integrated 778 nm stimulated Brillouin laser (SBL) can be used probe and lock to a hyperfine resolved two-photon transition in 87 Rb. Such an SBL can consist of an integrated silicon nitride (or other suitable material) ultra-high-quality factor resonator with a tuner (e.g., metal thermal) for scanning and modulating a cavity resonance. An SBL 5 kHz integral linewidth (ILW) and 40 Hz fundamental linewidth during tuning and modulation can be measured. In many embodiments, frequency modulation can be capable of engaging lock to atoms (e.g., engaging lock to a rubidium two-photon physics package). In many embodiments, narrow linewidths can enable probing of the transitions and extracting a linewidth of 467 kHz compared to 330 kHz natural linewidth. Several embodiments can include two-photon optical clocks with stability 2e-13 at 100 seconds, representing an 6× improvement in Allan deviation (ADEV) over the DBR.

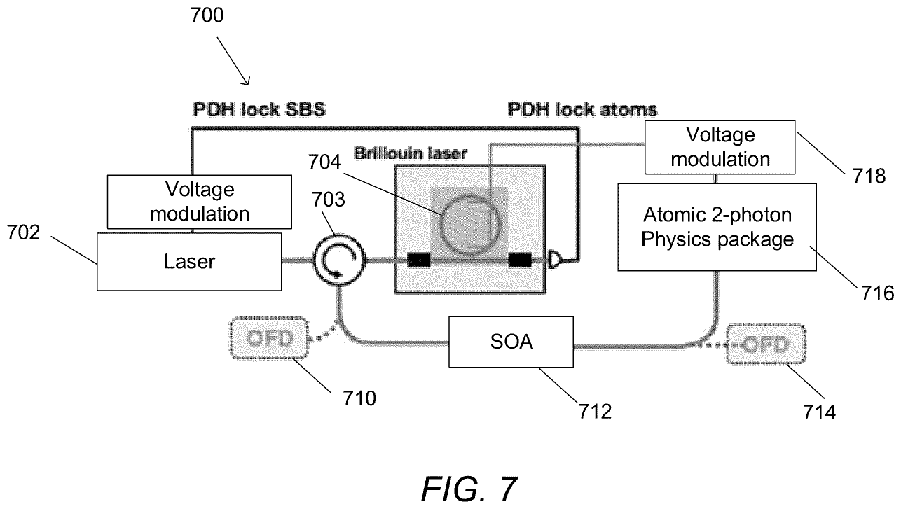

An example system diagram of a dual-stage lock and probe laser stabilization to a two-photon physics package is conceptually illustrated in FIG. 7. An example laser system 700 can include a laser 702. The laser 702 can be coupled to a resonator 704. An SBS outlet can link the system to a semiconductor optical amplifier (SOA) 712 and/or an optional first optical frequency discriminator (OFD) 710. The laser system 700 can be implemented on a photonic integrated circuit. After passing through the semiconductor optical amplifier (SOA) 712, lights can be directed into a second optional OFD 714. After passing through the SOA 712, light can be directed to an atomic (e.g., Rb) 2-photon physics package 716 and through voltage modulation 718 for controlling the modulation of resonator 704, Laser light directed coupled to the resonator 704 can be directed for PDH locking of the laser 702.

The laser 702 is incorporated into a two-photon atomic clock system as a probe for the Inflection Rb two-photon physics package. The SBS output can be taken from the drop port of a fiber circulator 703 and can be amplified with the semiconductor optical amplifier (SOA) 712. The physics package 716 can implements two-photon sub-Doppler fluorescence spectroscopy in a temperature-stabilized vapor.

While specific methods and/or systems for dual-stage lock and probe laser stabilization to a two-photon physics package are described above, any of a variety of methods and/or systems can be utilized as a dual-stage lock and probe laser stabilization to a two-photon physics package as appropriate to the requirements of specific applications. In certain embodiments, steps and/or components may be performed and/or configured in any order, sequence, and/or configuration not limited to the order, sequence and/or configuration shown and described. In a number of embodiments, some of the above steps may be executed or performed substantially simultaneously where appropriate or in parallel to reduce latency and processing times. In some embodiments, one or more of the above steps and/or components can be rearranged or omitted. Although the above embodiments of the invention are described in reference to a dual-stage lock and probe laser stabilization to a two-photon physics package, the techniques disclosed herein may be used in any type of integrated optical system. The techniques disclosed herein may be used within any of the integrated optical systems, laser systems, and/or other components and/or systems as described herein.

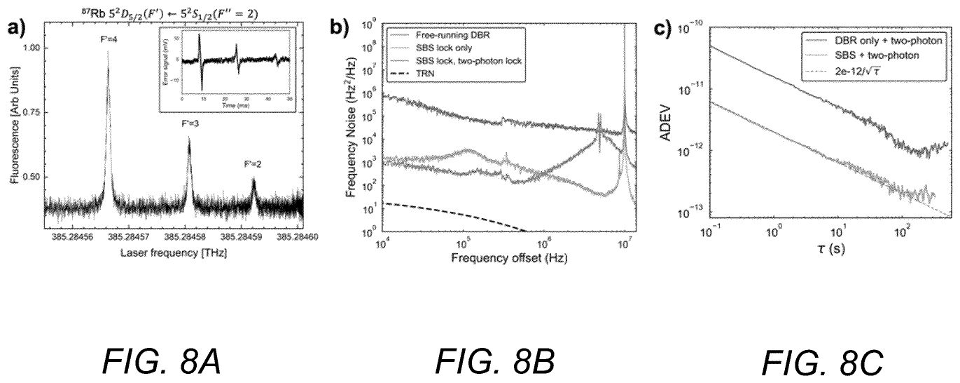

Example data obtained by testing a dual-stage lock and probe laser stabilization to a two-photon physics package are conceptually illustrated in FIG. 8A through 8C. FIG. 8A shows a two-photon signal scan. The inset is an error signal from a 10 kHz dither with modulator. FIG. 8B shows OFD frequency noise data. FIG. 8C shows ADEV stability measurements with a fiber frequency comb for two-photon locks using DBR laser only and DBR pumping SBS.

FIG. 8A shows an example of the two-photon fluorescence spectrum during a 130 ms ramp time of the Brillouin laser cavity resonance with a 30-sample average. To calibrate the frequency scale, a 2nd-order polynomial can be fit to the recorded fluorescence during the frequency scan and reported hyperfine intervals and peak ratios/or can be used to extract hyperfine linewidths. In some embodiments, an average hyperfine linewidth can be around 484±3 kHz which is close to the 330 kHz natural linewidth. Example measurement of laser output in several lock states with an unbalanced MZI (UMZI) optical frequency discriminator (OFD) are depicted in FIG. 8B. A free-running 778 nm DBR laser integral linewidth (ILW) and fundamental linewidths (FLW) of 151 kHz and 32 kHz. For the SBL a 5.1 kHz ILW and 40 Hz FLW, representing a 30× and 800× reduction of the pump linewidth, respectively are measured. By modulating (fmod=10 kHz) and scanning the SBL cavity fluorescence error signal can be generated and locked to the F′=4 peak (inset, FIG. 8A). In a dual-stage lock, the narrow atomic transition reduces laser frequency noise and tethers the laser to the narrow atomic 2-photon transition. For the combined SBS linewidth narrowing and two-photon transition lock an ILW of 6.3 kHz and 378 Hz FLW can be achieved, in accordance with embodiments of the invention. The ADEV of an example atomic clock is measured by mixing down with a self-referenced fiber frequency comb and compared to a passive hydrogen maser. With the SBL achieve a stability of 2e-12 at 1 second and 2e-13 at over 100 seconds, representing a 6 times lower ADEV over that measured with the DBR laser only.

In many embodiments, a frequency-tunable 778 nm integrated Brillouin laser in a compact package can show probing and locking to a Rb two-photon transition for an atomic clock. Some embodiments, can have 40 Hz fundamental and 5 kHz integral linewidths maintained over >10 kHz frequency modulation and stabilization to a rubidium two-photon transition resulting in stability of 2e-13 at 100 s.

While the above description contains many specific embodiments of the invention, these should not be construed as limitations on the scope of the invention, but rather as an example of one embodiment thereof. Accordingly, the scope of the invention should be determined not by the embodiments illustrated, but by the appended claims and their equivalents.

What is claimed is:

1. A laser system on a photonic integrated circuit, the photonic integrated circuit comprising:
at least one laser with an optical frequency the at least one laser stabilized to an at least one frequency reference, wherein the at least one laser is locked to the at least one frequency reference;
at least one photodiode and at least one laser current servo for locking the at least one laser to the at least one frequency reference; and
at least one modulator configured to modulate a resonator, wherein the modulator received an input from an optical frequency discriminator system and the optical frequency system receives an optical input from a laser output,
wherein the at least one frequency reference is a resonator, the resonator comprising a waveguide core and a tuner, wherein the tuner is laterally offset from the waveguide core.

2. The photonic integrated circuit of claim 1, wherein the tuner comprises a tuner configured by a tuning effect, the tuning effect selected from a list consisting of electro-optic tuning effect, stress-optic tuning effect, current-injection tuning effect, and thermo-optic tuning effect.

3. The photonic integrated circuit of claim 1, wherein the laser optical frequency is selected from a list consisting of Deep UV, UV, near UV, Visible, Near IR, Mid IR and IR wavelengths.

4. The photonic integrated circuit of claim 1, wherein the at least one laser, the at least one photodiode, the at least one frequency reference, and the at least one modulator are integrated to an integrated circuit using a material selected from a group consisting of silicon nitride, tantalum pentoxide, alumina nitride, and alumina oxide.

5. The photonic integrated circuit of claim 1, wherein the photonic integrated circuit is CMOS foundry compatible waveguide circuit.

6. The photonic integrated circuit of claim 1, wherein the resonator waveguide core and resonator tuner are separated by a cladding layer, the cladding layer sufficiently thick to prevent optical interaction between the resonator tuner and the waveguide core.

7. The photonic integrated circuit of claim 1, wherein the resonator is configured to narrow a linewidth of the laser and reduce the laser frequency and phase noise.

8. The photonic integrated circuit of claim 1, wherein the resonator tuner is configured to tune the laser without affecting noise properties of the laser.

9. The photonic integrated circuit of claim 1, wherein the laser is from a list of lasers including Fabry-Perot, DFB, DBR, EDBR, self-injection locked and stimulated Brillouin laser.

10. A laser system on a photonic integrated circuit, the photonic integrated circuit comprising:
a laser with an optical frequency, the laser stabilized to a frequency reference, wherein the laser is locked to the frequency reference;
at least one photodiode and a first voltage modulator for locking the laser to the frequency reference;
a second voltage modulator configured to modulate the frequency reference, wherein the laser stabilized to the modulated frequency reference is input to a physics package; and
a PDH lock loop configured to lock the stabilized laser and frequency reference to an optical transition of atoms in the physics package,
wherein the frequency reference is a resonator, the resonator comprising a waveguide core and a tuner, wherein the tuner is laterally offset from the waveguide core.

11. The photonic integrated circuit of claim 10, wherein the tuner comprises a tuner configured by a tuning effect, the tuning effect selected from a list consisting of electro-optic tuning effect, stress-optic tuning effect, current-injection tuning effect, and thermo-optic tuning effect.

12. The photonic integrated circuit of claim 10, wherein the laser optical frequency is selected from a list consisting of Deep UV, UV, near UV, Visible, Near IR, Mid IR and IR wavelengths.

13. The photonic integrated circuit of claim 10, wherein the laser, the at least one photodiode, the frequency reference, and a first voltage modulator are integrated to an integrated circuit using a material selected from a group consisting of silicon nitride, tantalum pentoxide, alumina nitride, and alumina oxide.

14. The photonic integrated circuit of claim 10, wherein the photonic integrated circuit is CMOS foundry compatible waveguide circuit.

15. The photonic integrated circuit of claim 10, wherein the resonator waveguide core and resonator tuner are separated by a cladding layer, the cladding layer sufficiently thick to prevent optical interaction between the resonator tuner and the waveguide core.

16. The photonic integrated circuit of claim 10, wherein the resonator tuner is configured to narrow a linewidth of the laser.

17. The photonic integrated circuit of claim 10, wherein the resonator tuner is configured to tuning the laser without affecting noise properties of the laser.

18. The photonic integrated circuit of claim 10, wherein a laser output comes from a circulator, the circulator positioned along a waveguide, and located between the laser and the resonator.

19. The photonic integrated circuit of claim 10, wherein the physics package is a rubidium two-photon physics package.

20. The photonic integrated circuit of claim 10, wherein a laser output is provided to an optical frequency discriminator.
